(19) United States
(12) Patent Application Publication
(10) Pub. No.: US 2011/0089404 A1
(43) Pub. Date: Apr. 21, 2011

(54) Microfabrication of Carbon-based Devices Such as Gate-Controlled Graphene Devices

(75) Inventors: Charles M. Marcus, Winchester, MA (US); James R. Williams, Cambridge, MA (US); Hugh Olen Hill Churchill, Somerville, MA (US)

(73) Assignee: PRESIDENT AND FELLOWS OF HARVARD COLLEGE, Cambridge, MA (US)

(21) Appl. No.: 12/936,768

(22) PCT Filed: Apr. 23, 2009
(86) PCT No.: PCT/US09/41488

§ 371 Date: Dec. 26, 2010

Related U.S. Application Data
(60) Provisional application No. 61/125,365, filed on Apr. 24, 2008.

(51) Int. Cl. H01L 29/12; H01L 21/36

(52) U.S. Cl. 257/29; 438/478; 257/E29.068; 257/E21.461

(57) ABSTRACT

A graphene device includes a graphene layer and a back gate electrode connected to apply a global electrical bias to the graphene from a first surface of the graphene. At least two graphene device electrodes are each connected to a corresponding and distinct region of the graphene at a second graphene surface. A dielectric layer blanket-coats the second graphene surface and the device electrodes. At least one top gate electrode is disposed on the dielectric layer and extends over a distinct one of the device electrodes and at least a portion of a corresponding graphene region. Each top gate electrode is connected to apply an electrical charge carrier bias to the graphene region over which that top gate electrode extends to produce a selected charge carrier type in that graphene region. Such a carbon structure can be exposed to a beam of electrons to compensate for extrinsic doping of the carbon.

### CROSS-REFERENCE TO RELATED APPLICATION

This application claims the benefit of U.S. Provisional Application No. 61/125,365, filed Apr. 24, 2008, the entirety of which is hereby incorporated by reference.

### BACKGROUND OF THE INVENTION

This invention relates to forms of carbon such as graphene and carbon nanotubes, and more particularly relates to microfabrication of carbon-based electronic devices.

Graphene, a single-layer hexagonal lattice of carbon atoms, has recently emerged as a fascinating system for fundamental studies in condensed matter physics, as well as a candidate for novel sensors and post-silicon electronics. Carbon nanotubes (CNTs) and graphene are allotropes of carbon in which the carbon atomic orbitals rearrange to produce a solid in which electrical conduction is possible, as either a metallic or a semiconducting material. The differences in the electrical conduction properties of CNTs and graphene arise solely from the differences in their geometric structure. CNTs are solids in which the carbon atoms are arranged in a hexagonal lattice of a structure that is cylindrical and hollow. This structure is long in one direction, hundreds to thousands of nanometers, and short and confined in the other two directions, a few to tens of nanometers. This confinement is key to the CNT electronic properties. Depending on the diameter of the CNT, that is, how the CNT is “rolled up,” the electronic properties are either semiconducting or metallic. Exactly two-thirds of all CNT made are semiconducting while the remaining third are metallic, with the state-of-the-art CNT production technology unable to reliably make CNT of one type or the other.

Although graphene is also a structure that is formed out of hexagonal lattices of carbon atoms, graphene is long in two directions and short in the other direction, resembling a sheet of chicken wire. This two-dimensional structure, in contrast to the CNT structure, is always metallic. The unusual band structure of single-layer graphene makes graphene a zero-gap semiconductor with a linear, i.e., photon-like, energy-momentum relation near the points where valence and conduction bands meet. That is, a graphene sheet as-formed is always a metallic conductor.

Graphene has the ability to carry electric current with either of the two electronic charge carrier types, electrons or holes. The entire modern bipolar electronics industry is based on devices that employ holes and electrons in device materials. In the semiconductor materials conventionally used for bipolar electronics, mainly silicon and germanium, the control of the particular charge carrier type in a device material is primarily achieved by a physical doping process such ion implantation, resulting in the creation of hole and electron regions in the implanted material. Such a doping method permanently fixes the location of the electron or hole regions in a semiconducting device. In addition, ion implantation fixes the charge carrier density, i.e., the number of charge carriers, either electron or holes, per square meter of the semiconducting material and device.

It has been established that in startling contrast to this conventional charge carrier control by doping, control of electronic charge carrier type in graphene can be accomplished in a temporal fashion by the application of an electric field in the vicinity of a graphene region. Such an electric field can be produced by, e.g., a metal gate electrode provided near or at the surface of a graphene layer. A positive voltage on the gate electrode shifts the Fermi level of the graphene region under the electrode to produce a predominance of electron charge carriers in that region. A negative voltage on the gate electrode shifts the Fermi level of the graphene region under the electrode to produce a predominance of hole charge carriers in that region. A reversal of the voltage produces a corresponding reversal in charge carrier type. This phenomenon enables bipolar electronics in graphene to be completely reconfigurable, that is, a simple change in the gate electrode voltage allows for “on-demand” control of the carrier type and density that can be tuned to suit a particular graphene device application, and obviates the need for conventional physical and fixed doping, for instance via ion implantation.

### SUMMARY OF THE INVENTION

The invention provides graphene configurations for producing robust and reproducible gate-controlled graphene devices having an arbitrary number of p-n junctions defined by regions with selected electrical charge carrier types that are controlled temporally by one or more local gates.

In one example configuration, the invention provides a graphene device that includes a graphene layer and a backgate electrode connected to apply a global electrical bias to the graphene from a first surface of the graphene layer. At least two graphene device electrodes are provided. Each device electrode is connected to a corresponding and distinct region of the graphene at a second graphene surface. A dielectric layer blanket-coats the second graphene surface and the device electrodes. At least one top gate electrode is disposed on the dielectric layer and extends over a distinct one of the device electrodes and at least a portion of a corresponding graphene region.

With this arrangement, each top gate electrode can be connected to apply an electrical charge carrier bias to the graphene region over which that top gate electrode extends to produce a selected charge carrier type in that graphene region. As a result, an arbitrary number of p-n junctions can be induced in the graphene. A wide range of electronic devices and systems, including reconfigurable circuit wiring systems, can be produced with this configuration, and a wide range of basic material phenomena can be effectively studied with the configuration.

In a further aspect, to enable the formation of such graphene devices, the invention provides a method for forming a material layer on a carbon structure, such as a carbon nanotube, a graphene region, a fullerene structure, or other carbon structure. In the method, a carbon surface of a carbon structure is exposed to at least one functionalization species that non-covalently bonds to the carbon surface while providing chemically-functional groups at the carbon surface. Then the chemically-functionalized carbon surface is exposed to a beam of electrons to compensate for extrinsic doping of the carbon surface. This process enables the production of passivated and undoped carbon surfaces for use in carbon-based electronic devices and systems. Other features and advantages of the invention will be apparent from the following description and accompanying drawings, and from the claims.

### BRIEF DESCRIPTION OF THE DRAWINGS

FIGS. 1A-1B are schematic side views of two example graphene p-n junction devices provided by the invention and having a single top gate;

FIGS. 2A-2C are a schematic side representations of the device of FIG. 1B and two different charge carrier arrangements of that device, respectively, in accordance with the invention;

FIGS. 3A-3C are schematic side views of a further example graphene p-n junction device provided by the invention, having multiple top gates, in three different charge carrier arrangements in accordance with the invention;

FIGS. 4A-4B are schematic side views of a further example graphene p-n junction device provided by the invention, having multiple top gates and multiple p-n junctions, in two different charge carrier arrangements in accordance with the invention;

FIGS. 4C-4D are schematic side views of a further example graphene p-n junction device provided by the invention, having a single top gate and multiple p-n junctions, in two different charge carrier arrangements in accordance with the invention;

FIGS. 5A-5B are schematic top views of a p-n junction circuit arrangement, provided by the invention, in two different wiring configurations in accordance with the invention;

FIG. 6 is a schematic representation of molecular species forming functionalization and dielectric layers on a graphene layer in accordance with the invention;

FIG. 7 is a schematic side view of an extrinsically undoped carbon nanotube including functionalization, dielectric, and gate material layers in accordance with the invention;

FIGS. 8A-8C are plots of differential conductance as a function of voltage of a carbon nanotube in a pristine state, after functionalization with NO2 and tetrakis hafnium, and after electron beam exposure in accordance with the invention, respectively,

FIGS. 9A-9D are plots of resistance and current as a function of voltage for an experimental graphene device having a configuration like that of the example device in FIG. 1A; and

FIGS. 10-10F are plots of conductance and magnetic field as a function of applied voltage for an experimental graphene device having a configuration like that of the example device in FIG. 1A.

### DETAILED DESCRIPTION OF THE INVENTION

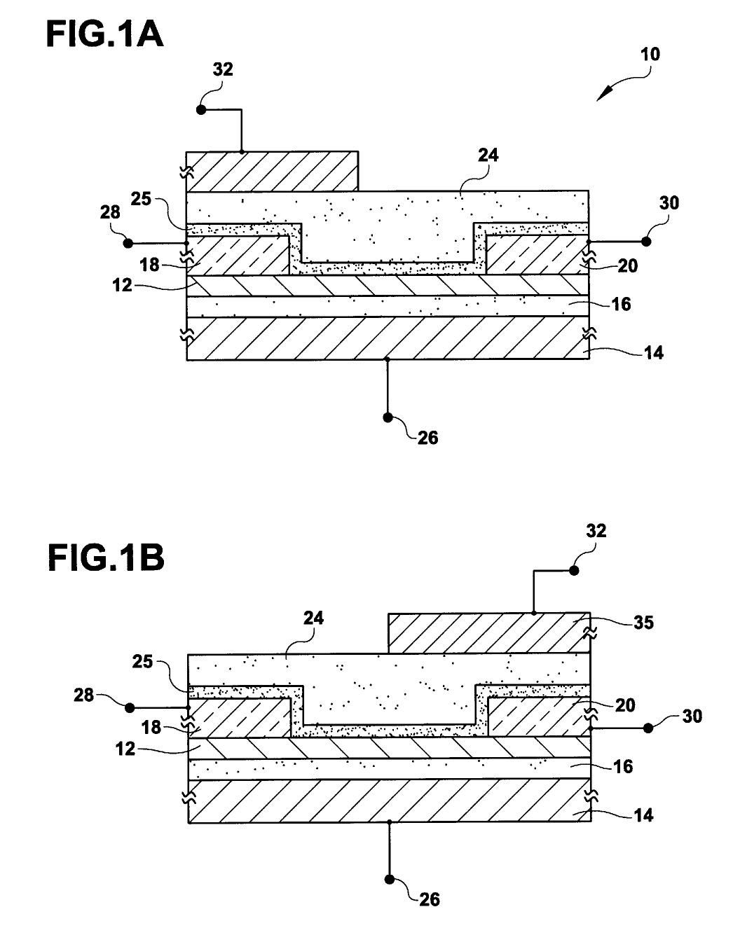

Referring to FIG. 1A, there is shown a schematic cross-sectional view of an example graphene p-n junction device 10 provided by the invention. For clarity the dimensions of the device are not shown to scale. The device includes a layer of graphene 12 that in this example is configured with voltage biasing to produce one region of the layer biased as p-type and one region of the layer biased as n-type, in the manner described below. Hereinafter the term “graphene” is meant to refer to a single layer of carbon atoms or a few layers of carbon atoms, i.e., few-layer graphene; the devices and fabrication processes described below are not limited to a single layer of carbon atoms and are intended to be applicable to multi-layers of carbon atoms or other carbon structures, as described below.

As shown in FIG. 1A, global control of the carrier type in the graphene is from the backside surface of the device, with a backgate electrode 14 that can be electrically insulated from the graphene 12 by, e.g., an insulating layer 16 if desired. Electrical device connection to the regions of the graphene to be biased n-type and p-type are made with device electrodes 18, 20, that directly contact the graphene. A local top gate 22 is provided directly above one of the device electrodes, in this example, over the left electrode 18, and extends part way over the graphene sheet to define a selected carrier type region in the graphene. The top gate is electrically insulated from the graphene 12 and the device electrodes 18, 20 by a gate oxide layer 24. As explained in detail below, the invention provides a functionalization layer 25 that is preferably included on the graphene to fully enable formation of the gate oxide layer without impacting the electrical properties of the graphene. Electrical connections 26, 28, 30, 32 are provided to the back electrode 14, device electrodes 18, 20, and local top gate 22, respectively.

FIG. 1B is a schematic cross-sectional view of a further example graphene p-n junction device 33 provided by the invention that is equivalent to the first example in FIG. 1A. This device similarly includes a layer of graphene 12 and a backgate electrode 14 that can be electrically insulated from the graphene 12 by an insulating layer 16, and device electrodes 18, 20, that directly contact the graphene. A local top gate 35 is here provided above the right device electrode 20 and extends over part of the right portion of the graphene sheet to define a selected carrier type region in the graphene. The top gate is electrically insulated from the graphene 12 and the device electrodes 18, 20 by a gate oxide layer 24 and a functionalization layer 25, described in detail below. Electrical connections 26, 28, 30, 32 are provided to the back electrode 14, device electrodes 18, 20, and local top gate 22, respectively.

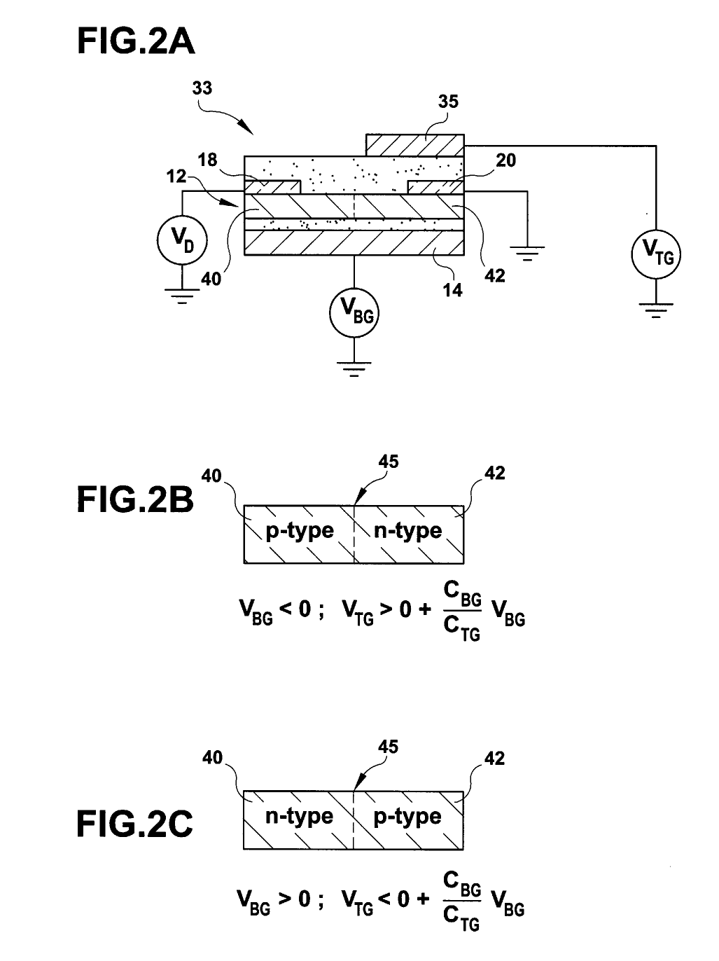

With these graphene arrangements, the invention provides a temporally-controllable graphene p-n junction device in the manner shown in FIGS. 2A-2C. In FIG. 2A the graphene p-n junction device 33 is represented highly schematically to focus on the voltage biasing for p-n junction device operation. With this arrangement, a backgate voltage, V_{BG}, is applied to the backgate electrode 14. A device voltage, V_{D}, is applied between the device electrodes 18, 20, for device operation. A top gate voltage, V_{TG}, is applied to the local top gate 35. Depending on the relative top gate and backgate voltages, two distinct graphene regions 40, 42 are defined, one being n-type and the other being p-type, with a junction 45 at the border of the two regions.

Referring to FIG. 2B, with the backgate voltage set as V_{BG}<0, and the top gate voltage set as V_{TG}>0+(C_{BG}/C_{TG})·V_{BG}, where C_{TG} and C_{BG} are the capacitances associated with the top gate and the backgate, respectively, the graphene region 42 under the top gate 35 is rendered n-type and the opposing region 40 is rendered p-type. The junction 45 between the n-type and p-type regions is at some point between the device electrodes 18, 20.

This p-n junction arrangement can be reversed at will by applying the biasing of FIG. 2C. Here the backgate voltage is set as V_{BG}>0, and the top gate voltage is set as V_{TG}<0+(C_{BG}/C_{TG})·V_{BG}, where C_{TG} and C_{BG} are the capacitances associated with the top gate and the backgate, respectively. With this biasing, the graphene region 42 under the top gate 35 is reversed to p-type and the opposing region 40 is reversed to n-type. The junction 45 between the n-type and p-type regions is again at some mid-point between the device electrodes 18, 20.

With this example it is demonstrated that this graphene device of the invention enables temporal electronic control of the graphene layer to form a single p-type graphene region directly adjacent to a single n-type graphene region, with the carrier types of the two regions being reversible at will. Only one p-n junction is formed in this first example graphene device of the invention but as described below, any arbitrary number of p-n junctions can be formed based on the number of top gates included in a device. In the example just described, a local top gate is disposed over one of two graphene regions to be defined and is disposed over the device electrode that is positioned at that region. The top gate controls the electrical charge carrier type and density of a graphene region that extends substantially only under the top gate. The top gate therefore must extend over at least a portion of a region to be controlled to a selected charge carrier type.

This graphene p-n junction device and the ability to control its doping profile temporally provide the foundation for a graphene-based bipolar technology that can surpass the current silicon-based bipolar technology in performance and application. In addition, beyond the myriad applications for graphene-based p-n junction devices in general, such a graphene p-n junction device is of great interest for studying many low-dimensional condensed matter physics phenomena. For instance, recent theory predicts that a local step in potential would allow solid-state realizations of relativistic, i.e., “Klein,” tunneling, and a surprising scattering effect known as Veselago lensing, comparable to scattering of electromagnetic waves in negative-index materials. The graphene p-n junction device of the invention thereby provides a platform for both device design as well as study of physical phenomena.

The invention further provides graphene device and circuit arrangements in which more than one in a plurality of graphene regions are separately controlled by a corresponding local top gate. As demonstrated below, these arrangements are temporally reconfigurable with any selected number of p-type and n-type graphene regions, each that can be individually addressed and with local top gate control, can be individually reversed in electronic charge carrier type.

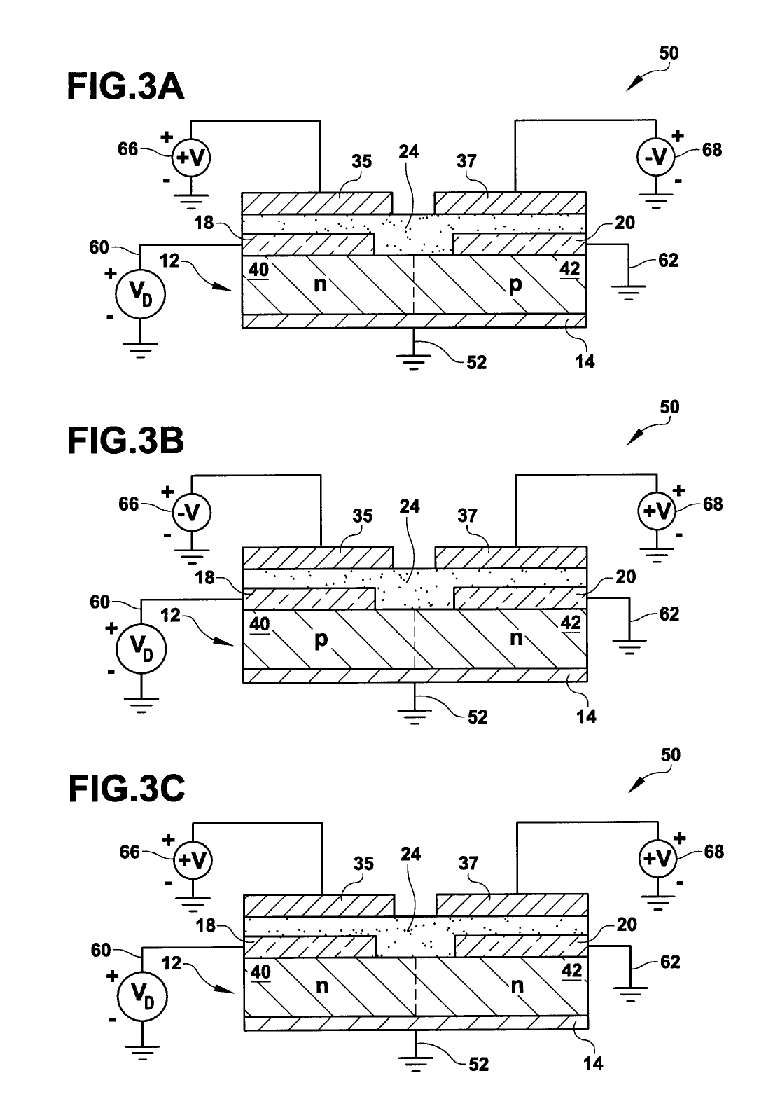

Referring to FIGS. 3A-3B, this configuration is schematically represented for a first example of a single p-n junction graphene device 50. The graphene device here includes a graphene layer 12 having a first region 40 and a second region 42 that are defined with charge carrier types based on the applied top gate voltages as described below. For clarity, a global backgate electrode 14 is here shown biased at ground. Device electrodes 18, 20 are biased with a selected device voltage, V_{D}, applied between the electrodes.

Local top gate electrodes 35, 37 are provided over the graphene, separated from the graphene by a gate insulator 24 and a functionalization layer that is not here shown for clarity. With the first top gate electrode 35 biased with an appropriate positive voltage 66 and the second top gate electrode 37 biased with an appropriate negative voltage 68, an n-type graphene region 40 is formed under the first top gate electrode 35 and a p-type graphene region 42 is formed under the second top gate electrode 37. The required top gate bias voltages are to be understood to include a consideration of device capacitances, as in FIGS. 2B-2C.

As shown in FIG. 3B, the top gate voltages can be each controlled to reverse the polarity of the p-n junction configuration of FIG. 3A. With the first top gate electrode 35 biased with an appropriate negative voltage 66 and the second top gate electrode 37 biased with an appropriate positive voltage 68, the graphene region 40 under the first top gate electrode 35 is reversed to p-type and the graphene region 42 under the second top gate electrode 37 is reversed to n-type; the polarity of the p-n junction is thusly reversed. This localized control can be extended, as shown in FIG. 3C, with both the first and second top gate electrodes 35, 37 biased with appropriate positive voltages 66, 68, whereby the graphene region 40 under the first top gate electrode 35 is reversed back to n-type, as in FIG. 3A, and as in the adjacent n-type graphene region 42. This configuration eliminates the p-n junction from the device.

This example demonstrates that the graphene layer can be electrically controlled locally with top gates to form two adjacent graphene regions of opposite charge carrier type, producing a p-n junction at the interface of the regions, then can be controlled to reverse the polarity of the p-n junction, and further can be controlled to set the regions to be of the same charge carrier type, thereby eliminating the p-n junction entirely. The local top gating arrangement provided by the invention enables this control; the charge carrier type of each region is reversed simply by reversal of a gate electrode voltage from +V to −V or from −V to +V. While this procedure is here demonstrated for a single graphene p-n junction device, it is applicable to all graphene p-n junction device and circuit arrangements provided by the invention.

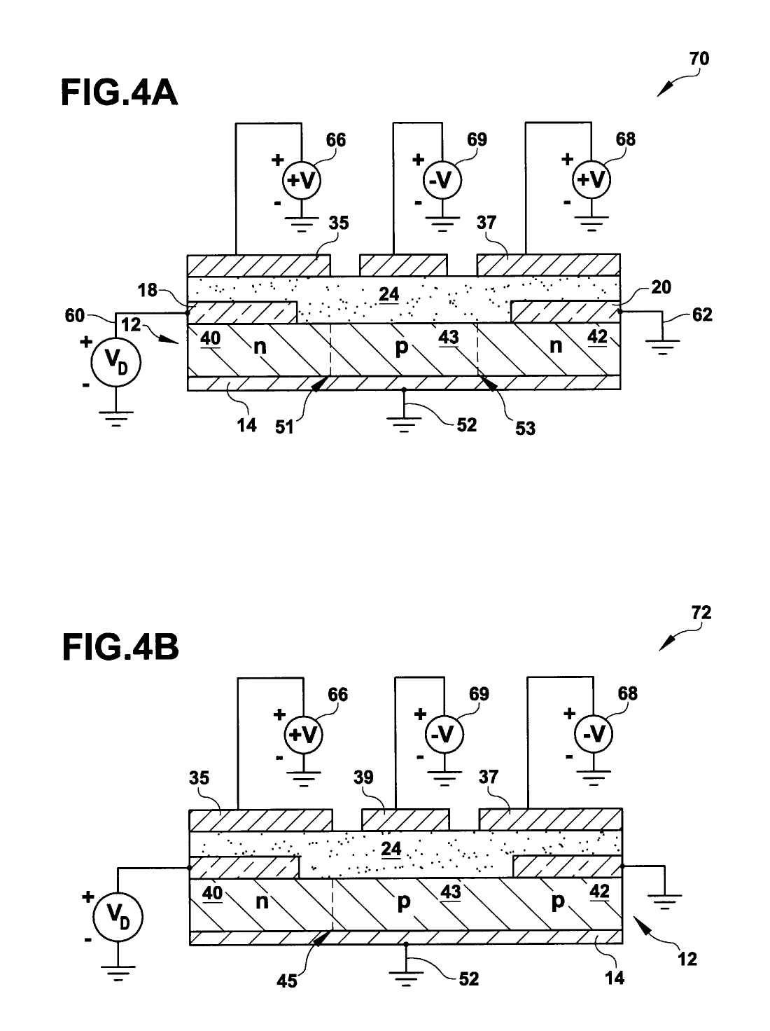

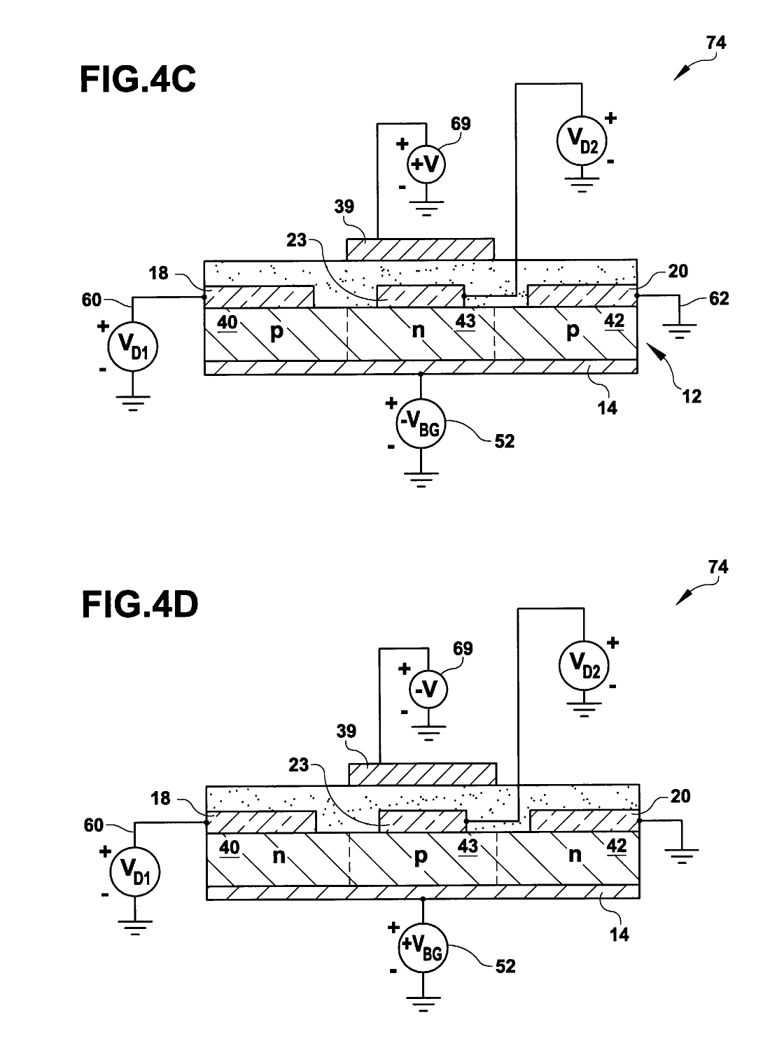

For example, referring to FIGS. 4A-4B, this paradigm is extended to a two-junction graphene device 70. The graphene device here includes a graphene layer 12 having a first region 40, a second region 42, and a third region 43 each of which are formed with a selected carrier type by application of a selected voltage applied to a top gate electrode disposed atop that region. For clarity, a global backgate electrode 14 is here shown biased at ground. Device electrodes 18, 20 are biased with a selected device voltage, V_{D}, applied between those electrodes.

Local top gate electrodes 35, 37, 39 are provided over the graphene 12, separated from the graphene by a gate insulator 24 and a functionalization layer not here shown for clarity. With the first and second top gate electrodes 35, 37 biased with an appropriate positive voltage 66, 68 and the third top gate electrode 39 biased with an appropriate negative voltage 69, n-type graphene regions 40, 42 are formed under the first and second top gate electrodes 35, 37, and a p-type graphene region 43 is formed under the third top gate electrode 39, producing an n-p-n arrangement for, e.g., a transistor device. The applied top gate bias voltages are to be understood to include a consideration of device capacitances, as in FIGS. 2B-2C.

Note in this configuration that no device electrode is disposed under the third top gate electrode 39. The invention does not require that each and every top gate be paired with a corresponding device electrode. For the graphene device 70 of FIG. 4A, if there is no need to make electrical contact to the third graphene region 43, then no device electrode need be provided at that region. But with local top gating of all three regions, the polarity of the two p-n junctions 51, 53, of the device can be reversed, and one or both of the p-n junctions can be eliminated.

Referring to FIG. 4B, such control of the p-n junctions can reconfigure the transistor device 70 of FIG. 4A to a diode or other single-junction device 72 as in FIG. 4B. Here the first top gate electrode 35 is biased with an appropriate positive voltage 66 and second and third top gate electrodes 37, 39, are biased with appropriate negative voltage 68, 69. With this top gate biasing, an n-type graphene region 40 is formed under the first top gate electrode 35 and two p-type graphene regions 42, 43 are formed under the second and third top gate electrodes 37, 39, resulting in a single p-n junction 45 under the three top gates that can be employed in a diode or other single-junction device.

Referring to FIG. 4C, in a further embodiment of the invention, a two-junction graphene device 74 is produced with a graphene layer 12 that is here configured with three device electrodes 18, 20, 23, adjacent to the graphene layer, for applying device voltage biases 60, 62, 63, between the three device electrodes. The third device electrode 23 is contacted at an edge of the device; the representation of this contact arrangement is schematic only to provide clarity of the device regions. In the configuration of FIG. 4C, a sole local top gate 39 is provided and is located over the third device electrode 23. This top gate 39 is biased with an appropriate positive voltage 69 that forms an n-type graphene region 43 under the top gate 39 and two p-type graphene regions 40, 42, adjacent to each side of the n-type region 43. With the backgate 14 biased at negative voltage, V_{BG}<0, only one top gate is here employed to form the three distinct graphene regions, and the three device electrodes provided for making electrical contact to each of the three graphene regions enable complete device control, with one of the three device electrodes provided under the top gate.

Referring also to FIG. 4D, the polarity of this two-junction graphene device 74 can be reversed by simply reversing the polarity of the top gate bias to an appropriate negative voltage 69 and reversing the polarity of the backgate voltage to a positive voltage, V_{BG}>0. The two p-type regions are then reversed to n-type regions 40, 42, and the n-type region is reversed to a p-type region 43. As stated just above, each of the three regions is individually contacted by device electrodes 18, 20, 23, that enable full control of the device before, during, and after the charge polarity and junction polarity reversals.

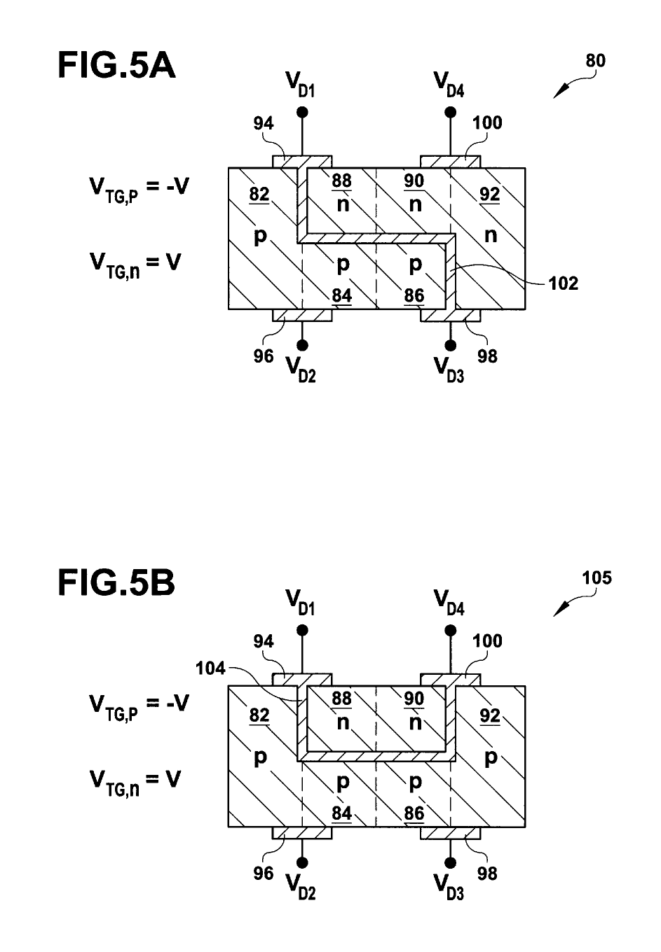

This control of p-n junction polarity and the formation and elimination of p-n junctions can be extended to any arbitrary number of junctions and to both device and circuit arrangements. For example, referring now to FIG. 5A, there is schematically shown an example four-terminal graphene circuit 80 in accordance with the invention. To clarify this arrangement, the circuit is represented in a top-down view with the top gates not shown. Each of the three identified p-type graphene regions 82, 84, 86, and each of the three identified n-type regions 88, 90, 92, have a top gate that is physically located over the region and is biased with an appropriate polarity voltage, V_{TG,p}, and V_{TG,n}, in the manner described above to produce the indicated charge carrier type in that region. Each of the regions further is connected to one of four device contacts 94, 96, 98, 100. An arrangement of p-type and n-type regions such as this can only be achieved with the local top gating provided by the invention.

This graphene circuit 80 enables reconfigurable wiring by exploiting so-called “snake states” that exist at a p-n interface. Specifically, enhanced electrical conduction at each p-n interface effectively forms a one-dimensional wire that is physically located at the junction between each p-type and n-type region. With this condition set, the arrangement of the circuit 80 in FIG. 5A, results in an enhancement of conductance between the first and third device electrodes 94, 98, thereby forming a path of enhanced conduction, or a one-dimensional wire 102, between these electrodes 94, 98 solely through control of the top gate voltages to set the p-type and n-type regions as shown.

Referring also to FIG. 5B, the circuit therefore can be rewired to provide a different selected wiring connection 105, e.g., to connect the first and fourth device electrodes 94, 100, by switching the polarity of the top gate over one region 92, reversing the charge carrier type of that region 92 from n-type to p-type. Here the circuit connection of the first arrangement 80 is eliminated and a new path of enhanced conduction 104 is formed, between the first and fourth device electrodes 94, 100. Any number of p-n junction circuit configurations like these can be controlled to thusly form temporal wiring connections between selected device electrodes.

These examples demonstrate that in accordance with the invention, each designated region of graphene to be controlled as a specific charge carrier type can be individually controlled with a corresponding top gate as-desired, but need not be; in either case, adjacent n-type and p-type conducting regions of graphene can be controlled to coexist by individual biasing of at least one of the adjacent regions. As a result, an arbitrary number of p-n junctions, including a single p-n junction, can be produced within a single graphene layer in accordance with the invention. Each distinct charge carrier region produced in the graphene layer with a corresponding local top gate can also be individually contacted under the top gate for device biasing and operational device control.

The invention provides specific processes for fabricating the graphene devices, circuits, and systems of the invention. It is recognized in accordance with the invention that for any graphene-based technology to succeed, the graphene behavior must meet the demands of modern electronics including stability and reproducibility. In general, stable electronics require that the properties of a device remain static over time. But graphene is known to interact with water in even only relatively humid environments, causing electronic charge hole doping of an exposed graphene region. The resulting hole charge carrier concentration in the graphene is related to the amount of water in the environment and, therefore, changes as the ambient humidity changes. In pristine graphene, i.e., graphene with no external doping, there is no excess electron or hole charge carrier concentration. The excess charge carrier concentration in graphene caused by extrinsic doping due to environmental conditions gives rise to reduced mobility in a graphene device, which places limits on the speed at which the device can operate. Also, for a given electric field range, extrinsic doping limits the carrier density and, if the doping is strong enough, the carrier type that can be utilized in a graphene device. The level of doping in a graphene device can be ascertained by sweeping the voltage, V, on a gate electrode while measuring the resistance of the device. If the peak in resistance, or corresponding dip in conductance, is at or very near the point of zero voltage bias, the device is undoped. If the peak in resistance occurs very far away from the zero voltage bias, the device is doped.

It is recognized in accordance with the invention that permanent prevention of external doping of graphene in a graphene device is particularly preferred to preserve graphene device performance characteristics. To prohibit such external doping, in accordance with the invention a graphene layer to be employed in a device or circuit is protected to prevent environmental changes to the device in which the graphene is employed.

The form of this graphene protection can be implemented as a function of a desired device configuration. For example, where one or more local top gates are employed to control regions of a graphene sheet, the gates are separated from the graphene sheet by a gate oxide layer. The gate oxide layer can operate to shield the graphene from the environment if, in accordance with the invention, the oxide layer is a blanket layer, not a regional or sectioned area, and the blanket layer covers the entire graphene surface, not just the regions directly beneath the gate electrodes, to protect the entire graphene surface from the environment and thereby prevent unintended doping of the graphene surface.

Thus, it is preferred to blanket-passivate a graphene layer or device to limit the transient nature of the device properties that would be produced in a humid environment. Local oxide formation, rather than blanket formation, would not fully passivate a graphene device; leaving exposed graphene surface areas that can absorb molecules, resulting in reduced device functionality. In addition, local oxide formation requires serial processing, in turn requiring long processing times for wafer-scale device fabrication.

Because graphene is very reactive with even its immediate environment, the choice of a blanket gate oxide material is particularly important. Many physical deposition methods result in amorphous oxides that can dope a graphene layer such that the layer exhibits the aforementioned degraded qualities. It is further discovered in accordance with the invention that the surface of graphene is chemically inert to many oxide deposition methods like Atomic Layer Deposition (ALD), preventing all oxide growth by that technique.

In accordance with the invention, to enable the formation of a selected oxide blanket layer on a graphene sheet, a nonconvalent functionalization layer is first provided on the surface of the graphene layer in a manner that provides functional species that can react with deposition precursors to form a blanket coating of a selected oxide. Specifically, functionalization layer is provided to impart a catalytically-suitable surface for growth of oxides, such as high-k dielectrics, via vapor processes such as ALD. The functionalization layer also passivates the graphene surface such that an oxide formed on the functionalization layer does not impact the electronic properties of the graphene.

The functionalization layer is compatible with a wide range of oxide type and deposition methods. For ALD, the functionalization layer allows for the deposition of, e.g., Al₂O₃, HfO₂, and ZnO, all of which are commonly employed as high-k dielectric layers. The functionalization layer can also be employed for carrying out physical vapor deposition and chemical vapor deposition processes to form blanket oxide layers of, e.g., silicon dioxide, titanium oxide, or ferroelectric materials like lead zirconate titanate (PZT). With the functionalization layer in place on the graphene prior to the dielectric formation, the dielectric does not extrinsically dope the graphene or otherwise impact the electronic properties of the graphene layer.

The functionalization layer and blanket oxide layer are formed in accordance with the invention on a graphene layer once such is provided in place on a selected substrate or other structure. It is recognized that many techniques exist and are being developed to produce graphene sheets. The invention is not limited to any particular graphene production process or resulting graphene configuration. In one example process to produce a piece of graphene, a thin piece of graphite is first extracted from, e.g., a bulk piece of highly oriented pyrolytic graphite, such as SPI-1 grade graphite, from SPI Supplies, Structure Probe, Inc., www.2spi.com. The extraction is carried out using, e.g., an adhesive tape, such as 3M Mask PlusII—Water Soluble Wave Solder Tape, from 3M, www.3m.com, by applying the tape to the graphite. The graphite region that is extracted onto the tape is thinned by repeated exfoliation of the region with additional tape.

Prior to a final exfoliation step, a selected substrate is provided, onto which the graphene is to be arranged. In one example, where a graphene device with a backgate electrode is desired, a heavily doped substrate, such as an n⁺⁺ Si substrate, can be employed as the support substrate and as the backgate electrode. Where the backgate electrode is to be electrically isolated from the graphene, as in the configurations of FIGS. 1A-1B, a layer of oxide is provided on the top surface of the Si substrate. In one example, a layer of SiO₂, e.g., a 300 nm-thick, thermally grown layer of SiO₂, is formed on the silicon substrate and then is cleaned in acetone and isopropyl alcohol (IPA).

Tape from the final graphene exfoliation is pressed against the oxide layer on the substrate and rubbed gently, e.g., with the back of a tweezers, for some reasonable time, e.g., 10 seconds. The structure is then immersed in water, e.g., at 60° C., to dissolve the tape from the graphene, and the substrate is preferably again cleaned in acetone and IPA to remove any tape residue left on the graphene and substrate surface. The structure can then be viewed under an optical microscope to identify potential regions of graphene using the well-established condition in which a single layer of graphene causes a characteristic color shift that arises from thin-film interference and that is distinct from two, three or more such layers.

Other graphene formation and arrangement techniques can be employed and the invention contemplates the future development of graphene formation processes that are more efficient and effective than those currently employed. The invention is not limited to current graphene production processes and is applicable to a graphene layer produced by any method.

With a graphene sheet, layer, or region in place on a selected platform, such as a microelectronic substrate, a graphene device, circuit, or other system in accordance with the invention can be produced with the functionalization and blanket oxide layers described above. To demonstrate the graphene microfabrication processes of the invention, one example process for producing the devices of FIGS. 1A-1B is described below, but the invention is not limited to such. It will be readily apparent that this process is applicable to all of the graphene devices and circuits described above and indeed, to any graphene device in which the layer of graphene is to be electrically connected for biasing and for device or circuit operation.

Referring then back to FIG. 1A, in this example fabrication sequence, with a graphene layer 12 provided on an oxide layer 16 of a silicon substrate 14 as described above, electrically conducting device electrodes 18, 20 are formed directly on the graphene. It is preferred that the device electrodes be provided directly on the graphene, not separated from the graphene by functionalization or oxide layers. In one example process to form the device electrodes, a resist, e.g., PMMA, is spin-coated onto the graphene and lithography, e.g., electron-beam lithography, is carried out to define in the resist specified locations of graphene device electrodes. The electrode material is then deposited by, e.g., a physical deposition process such as thermal evaporation. In one example, the electrode material is provided as a 40 nm-thick layer of gold layered on top of a 5 nm-thick layer of titanium. Titanium can be preferred to ensure good electrical contact to the graphene and an upper gold layer can be preferred to prevent the titanium from oxidizing and to provide good electrode conductivity. Then using conventional lift-off techniques the resist is removed and the device electrodes 18, 20 are formed on the graphene. With the device electrodes in place, a blanket top gate oxide layer 24 in FIG. 1A is to be provided over the electrodes and the graphene to operate both as a gate oxide layer and as a layer of protection against the environment.

As explained above, in accordance with the invention, prior to such oxide layer formation, a functionalization layer is first formed over the graphene in a blanket fashion, thereby also covering the device electrodes. The functionalization layer provides chemically functional groups at the graphene surface to enable deposition of an oxide layer on the graphene surface. Preferably the functionalization layer only non-covalently bonds with the graphene surface while providing the chemically functional groups for enabling deposition of a material on the graphene surface.

In one functionalization layer formation process in accordance with the invention, the structure is cleaned, e.g., with acetone and IPA, and then inserted into an ALD reaction chamber, e.g., a Cambridge Nano Tech Savannah Atomic Layer Deposition Tool, Cambridge Nano Tech, Inc., www.cambridgenanotech.com. An ALD process is then carried out to form a functionalization layer that is based on precursors used in producing an upper oxide layer of Al₂O₃.

In one example functionalization/passivation process, nitrogen dioxide gas (NO₂) and trimethylaluminum (TMA) vapor are employed to form a functionalization layer. In this example process, the chamber is pumped down to a pressure of, e.g., about 0.3 torr. Next, the functionalization layer is deposited at room temperature with a number of cycles, e.g., about 50 cycles, of the following sequence. A 100 torr dose of NO₂ is first introduced into the chamber for, e.g., about 0.5 seconds and then pumped out. Following a 7 second purge under continuous flow of 20 sccm of nitrogen gas (N₂), a 1 torr dose of trimethylaluminum TMA vapor is pulsed into the chamber. The chamber is then purged for 2 minutes before beginning the next cycle.

With this functionalization layer in place, a thin layer is applied to prevent the functionalization layer from desorbing. Then the gate oxide is formed on the stabilized functionalization layer. For many applications, it can be preferred to form the gate oxide layer by the same process as the functionalization layer, e.g., by ALD. In one example process of such, immediately after the functionalization layer cycles, e.g., 50 ALD cycles of the process just above, a thin layer of Al₂O₃ is formed by ALD on the functionalization layer to prevent desorption. This thin layer is grown by, e.g., 5 ALD cycles at room temperature of, e.g., a 1 torr pulse of H₂O vapor followed by a 1 torr pulse of TMA vapor, under continuous flow of N₂, with 5 second-intervals provided between pulses.

A top gate oxide layer of, e.g., Al₂O₃, in this example, is then grown on the stabilized functionalization layer. In one example process, the ALD temperature is raised to about 225° C. and a selected number of cycles, e.g., 300 cycles, of a 1 torr pulse of H₂O vapor followed by a 1 torr pulse of TMA vapor, under continuous flow of N₂, with 5 second-intervals provided between pulses are carried out. In this process, each H₂O-TMA cycle adds about 1 Angstrom of Al₂O₃ to the layer. A 300-cycle process thereby produces a total oxide thickness of about 30 nanometers. Given the precision of the ALD formation process, a wide range of oxide thicknesses can be obtained as-desired. Oxide layers as thin as about 10 nm and as thick as desired, e.g., 100 nm or more, given that there is no upper limit on the oxide thickness, can be provided with this formation method. The method is also quite flexible in temperature; ALD growth can be carried out at temperatures as low as about 80° C. and as high as about 225° C.

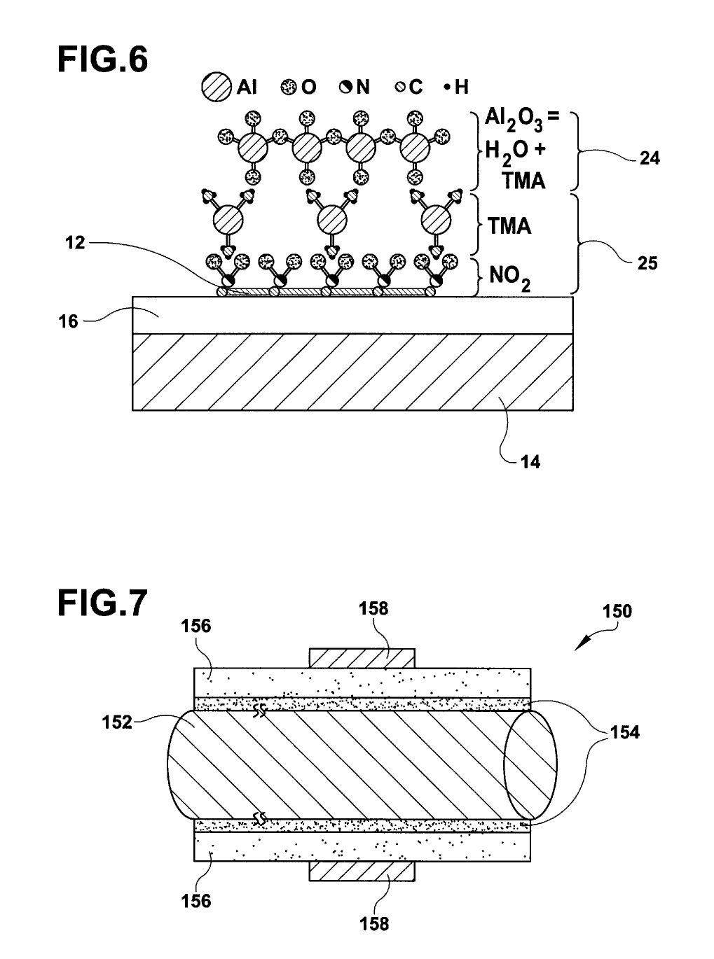

Referring to FIG. 6, with this oxide formation complete, a layer of Al₂O₃ 24 is provided on a functionalization layer 25 that blanket-coats the graphene 12 and any graphene region device electrodes, which are not shown here for clarity. The functionalization layer forms a non-interacting layer between the graphene and the top gate oxide layer, thereby preserving the electronic properties of the underlying graphene, and provides a surface that is catalytically suitable for the formation on the graphene of a gate oxide layer by a selected process such as ALD. Additional details and alternatives for functionalization layer formation are provided in U.S. Patent Application Publication US2008-0296537, entitled, “Gas-phase functionalization of carbon nanotubes,” published Dec. 4, 2008, the entirety of which is hereby incorporated by reference.

The invention is not limited to a particular functionalization layer formation process or functionalization layer material and can be conducted with any suitable set of precursors that non-covalently bind with the graphene surface to form a catalytically-active surface on which can be formed an oxide layer. For many applications, it can be preferred to employ as a functionalization layer precursor one of the precursors that is to be employed in formation of the subsequently formed oxide layer. Where a high-k dielectric is to be employed as the oxide layer, e.g., Hafnium Oxide (HfO₂) or zinc oxide (ZnO), or it can be preferred to provide a functionalization layer that is based on the selected oxide layer.

For example, given a graphene device process in which HfO₂ is to be employed as a top gate oxide material, a functionalization layer in accordance with the invention can employ an HfO₂ precursor in the formation of the functionalization layer. In one example process provided by the invention for producing such, a graphene layer, provided on a substrate and having device electrodes formed on the graphene, if desired, in the manner described above, is cleaned, e.g., with acetone and IPA, and the substrate is inserted into an ALD reaction chamber. The chamber is pumped down to a suitable pressure, e.g., about 0.3 torr. A number of ALD cycles, e.g., 50 cycles, are then carried out at, e.g., room temperature, to form a functionalization layer by the following process. A 100 torr dose of NO₂ gas is first introduced into the chamber for about 0.5 seconds and then pumped out. Following a 10 second purge under continuous flow of 20 sccm of N₂, a 1 torr dose of tetrakis(dimethylamido)hafnium(IV) (TDH) vapor is pulsed into the chamber. The chamber is then purged for, e.g., about 5 minutes before beginning the next cycle. The resulting functionalization layer is then capped, in the manner described above, to prevent desorption, by performing 5 cycles of 1-torr pulses of H₂O and 1.5 torr pulses of TDH, deposited at room temperature.

With this step, a stable functionalization layer is formed on the graphene layer and is ready for formation of a top gate oxide layer. Here, e.g., a layer of HfO₂ can be directly formed on the functionalization layer in the ALD chamber with the TDH precursor. The layer of HfO₂ can be deposited with a selected number of cycles each employing a 1 torr pulse of H₂O vapor and a 1.5 torr pulse of TDH vapor, under continuous flow of N₂ and with 20 seconds intervals between the pulses. This cyclic HfO₂ deposition can be performed at a variety of temperatures, e.g., between about 80° C. and about 300° C. The invention contemplates other functionalization layers and other oxide layers.

It has been discovered in accordance with the invention that even with a functionalization layer provided on a graphene surface, some functionalization and/or dielectric layers cause extrinsic doping of the graphene. This is not in general true; for example, an Al₂O₃ gate oxide layer formed on a TMA-based functionalization layer does not extrinsically dope or otherwise impact the electronic properties of an underlying graphene layer. But other oxide layers, for example, HfO₂, and NO₂-TDH-based functionalization layers, can extrinsically dope the underlying graphene layer, and further can reduce the electronic charge carrier mobility of the underlying graphene.

In accordance with the invention, after a functionalization layer is formed and/or after a top gate oxide layer is formed on a functionalized graphene device or circuit layer, it is preferred to conduct a current-voltage measurement of the device or circuit to determine if the functionalization layer or the oxide layer has impacted the electronic properties of the graphene. If the graphene does not exhibit the undoped current-voltage relation that is characteristic of pristine graphene, then a compensation process is carried out in accordance with the invention to restore the undoped characteristic of the graphene.

In one example compensation process provided by the invention, an energetic beam, e.g., an electron beam, is rastered across the surface of the functionalization layer and/or the oxide layer. In one example, a high-energy electron beam of electrons at any suitable voltage, e.g., about ˜30 keV, is rastered very quickly over the functionalization layer or oxide surface, to expose the surface to the electron beam for, e.g., about 10 ms/μm². This process can be carried out any suitable number of cycles, and the beam voltage and raster rate can be adjusted in a manner suitable for a given application, such that electrons penetrate a selected depth through the oxide and/or functionalization layers, to the underlying carbon surface, if desired.

It is understood in accordance with the invention that the electron beam exposure of a functionalization layer and/or oxide layer can passivate molecular dangling bonds that can exist in the oxide and underlying functionalization layer. The resulting passivated oxide and functionalization layers then do not need to accept or donate electrons from the graphene, rendering the graphene charge-neutral and preserving the unique electronic properties of the graphene. With this understanding, it can be preferred in accordance with the invention to evaluate the charge state of a graphene layer after top gate oxide formation to determine if this charge compensation process of the invention is warranted.

Now referring back to FIG. 1A, with an oxide layer 25 in place on a functionalization layer 25 over the graphene 12, one or more top gates 22 are formed on the oxide layer surface. It is to be recognized that any suitable gate dielectric material can be employed and the oxide layers described above are examples of such, but are not limiting.

The top gates can be formed in the manner of the device electrodes, with metal evaporation and lift-off patterning processes. For example, a resist such as PMMA can be spin-coated over the oxide surface and patterned by, e.g., electron-beam lithography to define regions for location of top gates. The top gate electrodes are then deposited by, e.g., thermally evaporating a 5 nm-thick layer of titanium and 40 nm-thick layer of gold in the manner described above, with a lift-off process employed to remove the metals and the resist in formation of one or more top gates. With the top gate formation complete, a locally-gated graphene p-n junction device in accordance with the invention is produced. Any of the example graphene devices illustrated in FIGS. 1-5 can be produced with this process, including any selected number of top gate electrodes and device electrodes, to produce any desired number of p-n junctions from a single p-n junction to an arbitrarily large number of p-n junctions.

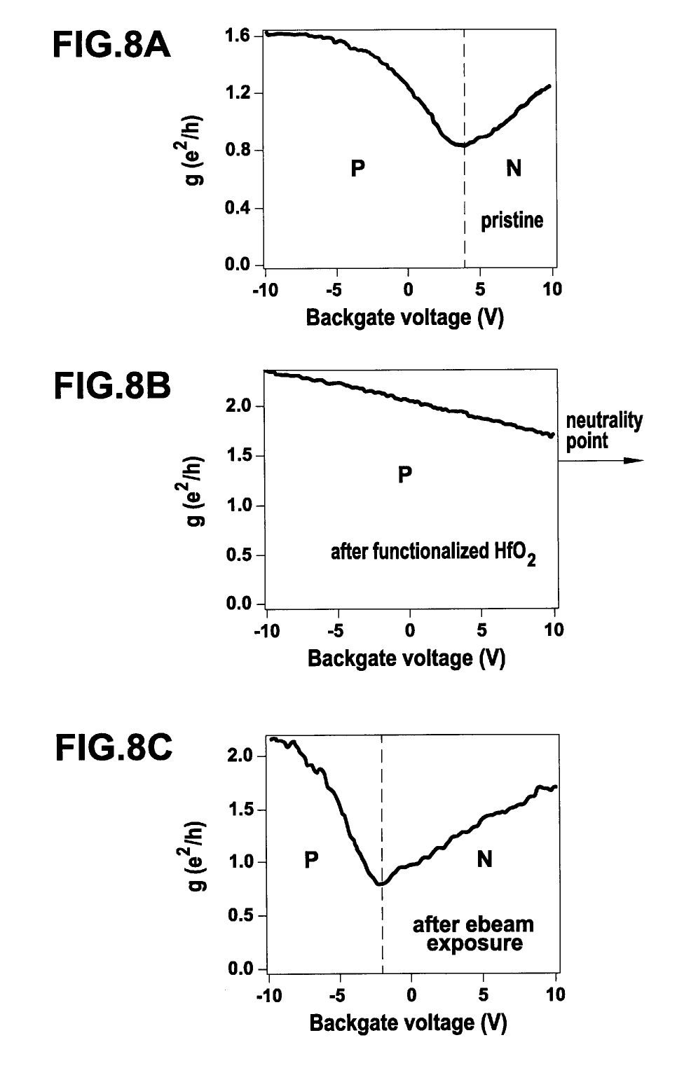

This graphene device production process can be extended to the production of electrically-gated carbon nanotube devices, or indeed, production of any carbon-based material device, whether or not including a gate electrode, in accordance with the invention. Referring to FIG. 7, there is provided by the invention such an example, here a gated carbon nanotube device 150. The carbon nanotube device includes a carbon nanotube 152 having a coaxial functionalization layer 154 on its cylindrical wall surface. A coaxial gate oxide layer 156 is provided over the functionalization layer, and a coaxial gate electrode 158 is provided at a selected point along the cylindrical wall surface of the carbon nanotube.

The functionalization layer 154 is formed on the nanotube in the manner described above, preferably with an ALD process that employs a precursor that is also used for forming the gate oxide layer 156, e.g., Al₂O₃ or HfO₂, or other selected gate oxide material. After the gate oxide layer is formed, the carbon nanotube is electrically contacted at its ends to determine if the nanotube has been extrinsically doped by the functionalization and/or oxide layers. If so, then the electron beam rastering process described above is carried out to compensate for the extrinsic doping and to render the nanotube with the characteristics of that of a pristine carbon nanotube.

After such electron beam rastering of the nanotube, a gate electrode can be formed on the nanotube, either at a specific point or coaxially around the circumference of the nanotube. The electron beam rastering of the gate oxide enables the production of a gated carbon nanotube that is not extrinsically doped by the environment or the layers deposited on the nanotube.

This demonstrates that the functionalization and oxide layer formation processes of the invention, in conjunction with the electron beam compensation process of the invention, can be applied to carbon-based structures in general, and is not limited to graphene. Indeed any carbon structure can be processed in accordance with the invention to produce a layer on a carbon surface of the structure and then to process the structure with an electron beam to produce a carbon structure that is not electrically doped. Carbon nanotubes, single layer and multi-layer graphene, general fullerene structures, or any structure having a carbon material surface, can be processed to produce a material layer on the carbon surface with the surface subsequently processed to be electrically undoped.

### Example I

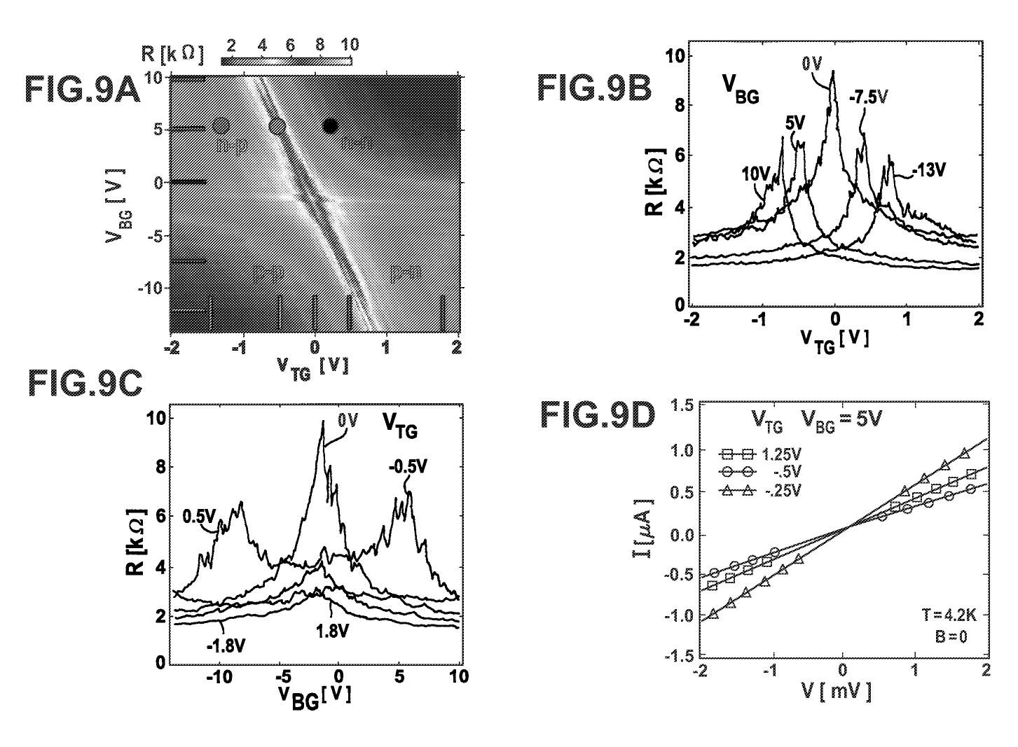

A semiconducting carbon nanotube was synthesized. and was configured for initial conductance characterization in a pristine state. A source-drain dc transport measurement was made by contacting ends of the nanotube. FIG. 8A is a plot of differential conductance, g, as a function of backgate voltage, V, for the pristine nanotube.

The carbon nanotube was then processed to form a functionalization layer and an oxide layer on the full circumference and length of the cylindrical sidewall of the nanotube. The nanotube was inserted into an ALD reaction chamber and the chamber was pumped down to a pressure of 0.3 torr. 5 ALD cycles were then conducted at room temperature to form a functionalization layer by the following process. A 100 torr dose of NO₂ gas was first introduced into the chamber for 0.5 seconds and then pumped out. Following a 10 second purge under continuous flow of 20 sccm of N₂, a 1 torr dose of tetrakis(dimethylamido)hafnium(IV) (TDH) vapor was pulsed into the chamber. The chamber was then purged for, e.g., about 5 minutes before beginning the next cycle.

The resulting functionalization layer was then capped and a layer of HfO₂ formed, with the capping layer produced by 5 ALD cycles of a 1 torr pulse of H₂O vapor and a 1.5 torr pulse of TDH vapor, under continuous flow of N₂, with 20 seconds intervals between the pulses at room temperature, and the oxide layer was formed by 300 cycles of this process at a temperature of 120° C. With the oxide and functionalization layers formed, a source-drain dc transport measurement was again made at room temperature as a function of gate voltage. FIG. 8B is a plot of differential conductance, g, as a function of voltage, V, for the structure. As shown by the plot, the neutrality point for the device was dramatically shifted away from the 0-volt point by the functionalization and oxide layers.

The HfO₂-coated nanotube was then exposed to rastering of an electron beam across the oxide surface to impose a dose of 100 μC/cm² on the structure. FIG. 8C is a plot of differential conductance, g, as a function of voltage, V, for the structure after the electron beam processing. The electron beam processing was found to clearly compensate for the extrinsic doping of the carbon nanotube to set the neutrality point back to around 0 V.

### Example II

A graphene device having the configuration of FIG. 1A was microfabricated in accordance with the invention. A 300 nm-thick layer of SiO₂ was thermally grown on a degenerately doped Si wafer. Graphene was exfoliated with a taping technique and applied to the oxide surface, and was identified by thin-film interference. Two device electrodes were formed by electron beam lithography and lift off with layers of titanium and gold, of 5 nm and 40 nm in thickness, respectively. A functionalization layer was then formed by the ALD process described above, employing 50 pulsed cycles of NO₂ and TMA at room temperature, in the manner given above. The functionalization layer was then stabilized by a 5-cycle ALD process of H₂O and TMA at room temperature, also in the manner given above. An oxide layer of Al₂O₃ was then formed over the stabilized functionalization layer by 300 ALD cycles of pulsed H₂O/TMA, at a temperature of about 225° C., yielding an oxide thickness of about 30 nm. To complete the device, a local top gate was formed as in FIG. 1A by electron beam lithography and lift off with layers of titanium and gold, of 5 nm and 40 nm in thickness, respectively. The top gate was located over one of the device electrodes just as in FIG. 1A.

The completed device was cooled in a ³He refrigerator and characterized at temperatures of 250 mK and 4.2 K. Differential resistance, R=dV/dI, where I is the current and V the source-drain voltage, was measured by standard lock-in techniques with a current bias of 1 nAᵣₘₛ at 95 Hz for T=250 mK (4.2K). The voltage across the two device electrodes contacting the graphene layer, was measured in a four-wire configuration, eliminating series resistance of the cryostat lines, but not contact resistance. Contact resistance was evidently low (˜1kΩ), and no background was subtracted from the data.

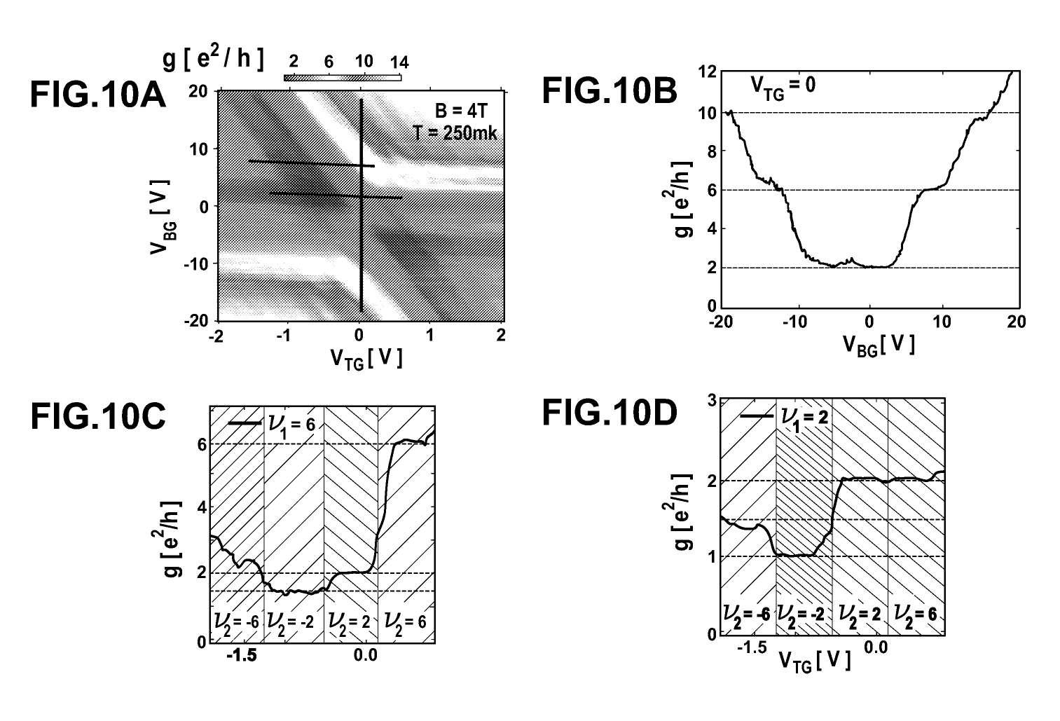

A measurement of the differential resistance, R, as a function of back-gate voltage, V_{BG}, and top-gate voltage, V_{TG}, at magnetic field B=0, is provided in the plot of FIG. 9A. This plot demonstrated independent control of carrier type and density in the two graphene regions. This two-dimensional plot reveals a skewed, cross-like pattern that separates the space of top gate and backgate voltages into four quadrants of well-defined carrier type in the two regions of the graphene. The horizontal (diagonal) ridge corresponds to charge-neutrality, i.e., the Dirac point, in region 1. The slope of the charge-neutral line in region 2, along with the known distances to the top gate and back gate, gives a dielectric constant κ˜6 for the functionalized Al₂O₃. The center of the cross at (V_{TG}, V_{BG})˜(−0.2 V, −2.5 V) corresponds to charge neutrality across the entire graphene layer. Its proximity to the origin of gate voltages demonstrates that the functionalized oxide did not chemically dope the graphene significantly.

Data for slices through this 2-D conductance plot at a fixed top gate voltage, V_{TG}, are shown in the plot of FIG. 9C. The slice at V_{TG}=0 shows a single peak commonly observed in devices with only a global back gate. Using a Drude model away from the charge-neutrality region, mobility is estimated at ˜7000 cm²/Vs. The peak width, height, and back-gate position are consistent with single-layer graphene and provide evidence that the electronic structure and degree of disorder of the graphene was not strongly affected by the oxide. Slices at finite |V_{TG}| reveal a doubly-peaked structure. The weaker peak, which remains near V_{BG}˜−2.5V at all V_{TG}, corresponds to the Dirac point of region 1. The stronger peak, which moves linearly with V_{TG}, is the Dirac point for region 2. The difference in peak heights is a consequence of the different aspect ratios of regions 1 and 2.

Horizontal slices through the 2-D plot of FIG. 9A at fixed V_{BG}, corresponding to the horizontal lines in FIG. 9A are shown in FIG. 9B. These slices show a single peak corresponding to the Dirac point of region 2. This peak becomes asymmetric away from the charge-neutrality point in region 1. The changing background resistance results from the different density in region 1 at each V_{BG} setting.

FIG. 9D is a plot of measured current, I, as a function of applied voltage, V, for the device, measured throughout the (V_{TG}, V_{BG}) plane. This plot indicates no sign of rectification in any of the four quadrants or at either of the charge-neutral boundaries between quadrants, as expected for reflectionless (“Klein”) tunneling at the p-n interface

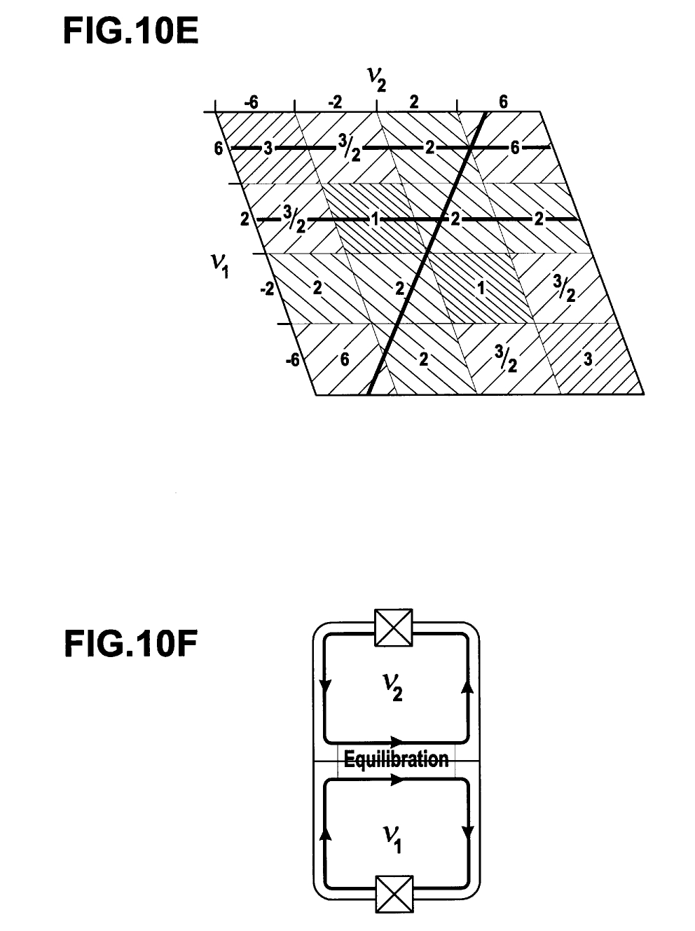

A plot of differential conductance, g=1/R, as a function of V_{BG} and V_{TG} with an applied magnetic field of B=4T is shown in FIG. 10A. A vertical slice of data taken at V_{TG}=0 through the p-p and n-n quadrants of the plot of FIG. 10A is shown in FIG. 10B. This plot reveals conductance plateaus at 2, 6, and 10 e²/h in both quadrants, demonstrating conclusively that the sample was single-layer and that the oxide did not significantly distort the Dirac spectrum.

In the quantum hall (QH) regime at large B, the Dirac-like energy spectrum of graphene gives rise to a characteristic series of QH plateaus in conductance, reflecting the presence of a zero-energy Landau level, that includes only odd multiples of 2 e²/h, that is, 2, 6, 10, . . . times e²/h, for uniform carrier density in the graphene layer. These plateaus can be understood in terms of an odd number of QH edge states, including a zero-energy edge state at the edge of the graphene layer, circulating in a direction determined by the direction of B and the carrier type. The situation is somewhat more complicated when varying local density and carrier type across the graphene layer.

QH features were investigated for differing filling factors υ₁ and υ₂ in regions 1 and 2 of the graphene layer. A horizontal slice through FIG. 10A at filling factor υ₁=6 is shown in FIG. 10C. Starting from the n-n quadrant, plateaus are observed at 6 e²/h and 2 e²/h at top-gate voltages corresponding to filling factors υ₂=6 and 2, respectively. Crossing over to the n-p quadrant by further decreasing V_{TG}, a new plateau at 3/2 e²/h appears for υ₂=−2. In the υ₂=−6 region, no clear QH plateau is observed. FIG. 10D provides a plot of data from a horizontal slice at υ₁=2 in FIG. 10A, showing 2 e²/h plateaus at both υ₂=6 and 2. Crossing into the n-p quadrant, the conductance exhibits QH plateaus at 1 e²/h for υ₂=−2 and near 3/2 e²/h for υ₂=−6.

For υ₁ and υ₂ of the same sign (n-n or p-p), the observed conductance plateaus follow an expression as:

$$g = min ( \vert {v}_{1} \vert , \vert {v}_{2} \vert ) \times \frac{{e}^{2}}{h} . \qquad ( 1 )$$

This relation suggests that the edge states common to both regions propagate from source to drain while the remaining |υ₁−υ₂| edge states in the region of highest absolute filling factor circulate internally within that region and do not contribute to the conductance. This picture is consistent with known results on conventional 2D electron gas systems with inhomogeneous electron density.

Recent theory addresses QH transport for filling factors with opposite sign in regions 1 and 2 (n-p and p-n). In this case, counter-circulating edge states in the two regions travel in the same direction along the p-n interface, as shown in FIG. 10F, which presumably facilitates mode mixing between parallel-traveling edge states. For the case of complete mode-mixing, that is, when current entering the junction region becomes uniformly distributed among the |υ₁|+|υ₂| parallel-traveling modes, quantized plateaus are expected (18) at values given by the expression:

$$g = \frac{\vert {v}_{1} \vert \vert {v}_{2} \vert}{\vert {v}_{1} \vert + \vert {v}_{2} \vert} \times \frac{{e}^{2}}{h} . \qquad ( 2 )$$

A table of the conductance plateau values given by Expressions 1 and 2 is shown in FIG. 10E. Plateau values at 1 e²/h for υ₁=−υ₂=2 and at 3/2 e²/h for υ₁=6 and υ₂=−2 are observed in experiment. Notably, the 3/2 e²/h plateau suggests uniform mixing among four edge stages (three from region 1 and one from region 2). All observed conductance plateaus are also seen at T=4K and for B in the range 4 to 8 T.

There was found some departures between the experimental data and Expressions 1 and 2, as represented in the grid of FIG. 10E. For instance, the plateau near 3/2 e²/h in FIG. 10D is seen at a value of ˜1.4 e²/h and no clear plateau at 3 e²/h is observed for υ₁=υ₂=6. It was speculated that the conductance in these regions being lower than their expected values is an indication of incomplete mode mixing. Also observed was an unexpected peak in conductance at a region in gate voltage between the two 1 e²/h plateaus at υ₁=+/−υ₂=2. This rise in conductance is clearly seen for |V_{TG}| values between 1 and 2 V and V_{BG} values between −5 and −2V. This may result from the possible existence of puddles of electrons and holes near the charge-neutrality points of regions 1 and 2, as previously suggested.

These examples demonstrate that graphene p-n junction devices of the invention enable both device operation and the study of physical phenomena in graphene layers.

With this description it is demonstrated that the invention provides carbon-based structures such as graphene p-n junction devices that can be arranged and controlled to include any number of p-n junctions, including a single p-n junction, with one or more device electrodes on the graphene layer being disposed underneath a top gate. Each region of graphene to be controlled with a selected charge carrier type by a local top gate can be individually contacted if desired. This enables distinct control of p-type and n-type regions, that can be adjacent to each other, and that can be provided even as a single p-n junction device or multiple-junction device or circuit arrangement. Unlike state-of-the-art silicon bipolar electronics, in which ion implantation is used to create fixed p-type and n-type regions having carrier densities that are also fixed, p-type and n-type charge carrier regions, regions of a graphene device of the invention can be temporally and separately controlled to be either n-type or p-type, and can be reversed to the opposite charge carrier type, with precise control over the carrier density, tailored to suit the function of the device. Completely reconfigurable bipolar graphene electronics are thereby provided by the invention. The graphene devices are temperature insensitive, because graphene is itself insensitive to temperature variation, and therefore graphene device operation from 4K all the way up to room temperature, can be achieved with a wide array of p-n junction device and circuit configurations.

Also as demonstrated above, the invention provides a microfabrication process for producing carbon-based structures, such as graphene p-n junction devices and circuits, with a technique for functionalizing a carbon surface prior to gate oxide formation. The functionalization layer blanket-coats the carbon surface to prevent extrinsic doping of the surface by the ambient environment, and enables the growth of a wide variety of top gate oxide layers, including ferroelectric and ferromagnetic layers, without altering the electronic properties of the undoped graphene. The invention provides an electron beam rastering process to compensate for any extrinsic doping of a carbon surface that occurs during microfabrication processing. The electron beam rastering process enables the production of carbon-based structures, such as graphene devices and circuits, that are electrically robust and exhibit reproducible performance characteristics. It is recognized, of course, that those skilled in the art may make various modifications and additions to the devices, circuits, and microfabrication processes of the invention without departing from the spirit and scope of the present contribution to the art. Accordingly, it is to be understood that the protection sought to be afforded hereby should be deemed to extend to the subject matter of the claims and all equivalents thereof fairly within the scope of the invention.

We claim:

1. A method for forming a material layer on a carbon structure comprising:
exposing a carbon surface of the carbon structure to at least one functionalization species that non-covalently bonds to the carbon surface while providing chemically-functional groups at the carbon surface; and
exposing the chemically-functionalized carbon surface to a beam of electrons to compensate for extrinsic doping of the carbon surface.

2. The method of claim 1 wherein exposing the chemically-functionalized carbon surface to a beam of electrons comprises rastering a beam of electrons across the carbon surface.

3. The method of claim 1 further comprising, before exposing the chemically-functionalized carbon surface to a beam of electrons, exposing the chemically-functionalized carbon surface to at least one material layer precursor species that deposits a material layer on the chemically-functionalized carbon surface.

4. The method of claim 1 wherein the carbon surface comprises a surface of a layer of graphene.

5. The method of claim 1 wherein the carbon surface comprises a cylindrical wall of a carbon nanotube.

6. The method of claim 1 wherein the functionalization species comprises NO₂.

7. The method of claim 1 wherein the functionalization species comprises a precursor selected from the group consisting of trimethylaluminum and tetrakis(dimethylamido)hafnium.

8. The method of claim 1 wherein the functionalization species comprises NO₂ and tetrakis(dimethylamido)hafnium.

9. The method of claim 1 further comprising forming a layer of oxide on the chemically-functionalized carbon surface before exposing the carbon surface to a beam of electrons.

10. The method of claim 9 wherein forming a layer of oxide comprises forming a layer of HfO₂.

11. The method of claim 1 wherein exposing a carbon surface of the carbon structure to at least one functionalization species comprises atomic layer deposition of a functionalization species on the carbon surface.

12. The method of claim 11 further comprising forming a layer of oxide on the chemically-functionalized carbon surface by atomic layer deposition.

13. A method for forming a material layer on a graphene layer comprising:
exposing a surface of the graphene to at least one functionalization species that non-covalently bonds to the graphene surface while providing chemically-functional groups at the graphene surface;
forming a layer of oxide on the chemically-functionalized graphene surface; and
exposing the layer of oxide and the chemically-functionalized graphene surface to a beam of electrons to compensate for extrinsic doping of the carbon surface.

14. A structure comprising:
a carbon material; and
a layer of HfO₂ disposed on a surface of the carbon material;
wherein the carbon material is electrically undoped.

15. The structure of claim 14 wherein the carbon material comprises a layer of graphene.

16. The structure of claim 14 wherein the carbon material comprises a carbon nanotube.

17. The structure of claim 14 further comprising a functionalization layer, under the HfO₂ layer, that is non-covalently bonded to the carbon material surface and that provides chemically functional groups bonded to the HfO₂ layer.

18. The structure of claim 17 wherein the functionalization layer comprises NO₂.

19. A graphene device comprising:
a graphene layer;
a backgate electrode connected to apply a global electrical bias to the graphene from a first surface of the graphene layer;
at least two graphene device electrodes, each device electrode connected to a corresponding and distinct region of the graphene at a second graphene surface;
a dielectric layer blanket-coating the second graphene surface and the device electrodes; and
at least one top gate electrode disposed on the dielectric layer and extending over a distinct one of the device electrodes and at least a portion of a corresponding graphene region.

20. The device of claim 19 wherein the at least one top gate electrode comprises two top gates electrodes each disposed on the dielectric layer and extending over a distinct one of the device electrodes and at least a portion of a corresponding graphene region.

21. The device of claim 19 further comprising a functionalization layer, under the dielectric layer, that is non-covalently bonded to the second graphene surface and that provides chemically-functional groups bonded to the dielectric layer.

22. The device of claim 21 wherein the functionalization layer comprises NO₂ and a species selected from the group consisting of trimethylaluminum and tetrakis(dimethylamido)hafnium.

23. The device of claim 19 wherein the dielectric layer comprises an oxide selected from the group consisting of Al₂O₃, HfO₂, and ZrO₂.

24. The device of claim 19 wherein the graphene layer is disposed on a substrate, over an oxide layer coating one surface of the substrate.

25. The device of claim 24 wherein the substrate comprises a silicon wafer.

26. The device of claim 24 wherein the substrate forms the backgate electrode.

27. The device of claim 19 wherein the graphene regions form a circuit wiring connection between device electrodes.

28. The device of claim 19 wherein the graphene regions form a single p-n junction with one p-type graphene region adjacent to one n-type graphene region.

29. The device of claim 19 wherein the graphene regions form a plurality of p-n junctions.

30. The device of claim 19 further comprising at least a third device electrode connected to a corresponding region of the graphene.

31. The device of claim 19 wherein the each of the at least one top gate electrode is connected to apply an electrical charge carrier bias to the graphene region over which that top gate electrode extends, to produce a selected charge carrier type in that graphene region.

32. The device of claim 19 wherein the at least one top gate electrode comprises at least three top gate electrodes each disposed on the dielectric layer over a distinct device electrode and at least a portion of a corresponding graphene region.

33. The device of claim 19 further comprising a third device electrode connected to a graphene region, and wherein the at least one top gate electrode comprises two top gate electrodes each disposed on the dielectric layer over a distinct device electrode and at least a portion of a corresponding graphene region to define two p-n junctions in the graphene.

34. A graphene device comprising:
a graphene layer;
a backgate electrode connected to apply a global electrical bias to the graphene from a first surface of the graphene layer;
at least two graphene device electrodes, each device electrode connected to a corresponding and distinct region of the graphene at a second graphene surface;
a dielectric layer blanket-coating the second graphene surface and the device electrodes; and
at least one top gate electrode disposed on the dielectric layer and extending over a distinct one of the device electrodes and at least a portion of a corresponding graphene region, connected to apply an electrical charge carrier bias to the graphene region over which that top gate electrode extends to produce a selected charge carrier type in that graphene region.
